(19) United States
(12) Patent Application Publication
(10) Pub. No.: US 2023/0151492 A1
(43) Pub. Date: May 18, 2023

(54) Direct Printing of Catalyst Inks

(71) Applicant: Science Applications International Corporation, Reston, VA (US)

(72) Inventors: John P. Timler, River Ridge, LA (US); David M. Morris, Bloomington, IN (US)

(21) Appl. No.: 17/527,607

(22) Filed: Nov. 16, 2021

(51) Int. Cl. G03F 7/00; B01J 37/34; B01J 23/44; B01J 35/00; C23C 18/38; C23C 18/16; C23C 18/30; C23C 18/20; C09D 11/107; C09D 11/14; C09D 11/03

(52) U.S. Cl. CPC G03F 7/0002; B01J 37/345; B01J 23/44; B01J 35/0013; B01J 35/006; C23C 18/38; C23C 18/1608; C23C 18/30; C23C 18/2053; C09D 11/107; C09D 11/14; C09D 11/03; B82Y 40/00

(57) ABSTRACT

Catalyst ink may be directly printed to a substrate using a stamp. Printed catalyst ink may converted to a pattern of one or more metal traces. Materials for a stamp and/or a substrate, and/or components of a catalyst ink, may be selected based on attraction of one or more of components of the catalyst ink to one or more print surfaces of the substrate and/or to one or more write surfaces of the stamp.

### GOVERNMENT LICENSE RIGHTS

This invention was made with Government support under Contract No. N00178-04-D-4119-FC46 awarded by the United States Navy. The Government has certain rights in this invention.

### BACKGROUND

Known lithographic approaches for manufacturing integrated circuits having high precision may be costly. As the scale of features decreases, optical lithography may require increasingly expensive masks for patterning along with complex exposure tools including high powered excimer lasers and stacks of precision ground lens elements to achieve desired resolution. For metallization processes, optical lithography may require eight processing steps (substrate metallization, photoresist deposition, photoresist cure, mask alignment, extreme ultraviolet exposure, photoresist development, metal etch, and photoresist removal) and associated manufacturing equipment. Nanoimprint lithography is a competing technology for creating smaller scale integrated circuits. But with metallization processes, nanoimprint lithography may require six process steps (substrate metallization, photoresist deposition, photoresist cure, stamp positioning/impression transfer, metal etch, and photoresist removal).

### SUMMARY

This Summary is provided to introduce a selection of some concepts in a simplified form as a prelude to the Detailed Description. This Summary is not intended to identify key or essential features.

Catalyst ink may be directly printed onto a substrate using a stamp. The printed catalyst ink may then be converted, by plating, to a pattern of one or more metal traces. The pattern may comprise micrometer scale features. The steps may be repeated an arbitrary number of times to replicate the pattern in different locations and/or on different substrates. To promote transfer of catalyst ink from the stamp to the substrate, materials for a stamp and/or a substrate, and/or components of a catalyst ink, may be selected so that attraction of one or more of components of the catalyst ink to one or more print surfaces of the substrate is greater than attraction of those one or more ink components to one or more write surfaces of the stamp. Metal traces and/or patterns may be formed by such steps in connection with fabrication of integrated circuits, system-on-chip assemblies, printed circuit boards, conformal patterns (e.g., for antenna arrays), and/or other articles.

These and other features are described in more detail below.

### BRIEF DESCRIPTION OF THE DRAWINGS

Some features are shown by way of example, and not by way of limitation, in the figures of the accompanying drawings and in which like reference numerals refer to similar elements.

FIG. 1 is a flow chart showing steps of an example method of direct stamp printing of a catalyst ink pattern and plating that pattern.

FIGS. 2A and 2B are respective plan and area cross-sectional views of an example stamp that may be used in the method of FIG. 1.

FIGS. 3A, 3B, and 3C are partially schematic area cross-sectional views showing an example of applying a catalyst ink to write surfaces of the stamp of FIGS. 2A and 2B.

FIGS. 4A, 4B, and 4C are partially schematic area cross-sectional views showing an example of transferring catalyst ink 40 to a print surface of a substrate.

FIG. 5A is a partially schematic plan view of a substrate print surface after transfer of catalyst ink.

FIG. 5B is a partially schematic plan view of the substrate print surface of FIG. 5A after plating of catalyst ink.

FIGS. 6A and 6B are partially schematic area cross-sectional views showing examples of substrate print surfaces.

FIG. 7 shows an example configuration of a stamp to provide laser or UV light treatment of catalyst ink.

FIG. 8 shows an example configuration of a stamp to provide sonification of catalyst ink.

### DETAILED DESCRIPTION

A patterned stamp may be used to replicate patterns of catalyst ink on a substrate. One or more write surfaces of the stamp may be coated with a layer of catalyst ink. The catalyst ink coating the stamp write surface(s) may be brought into contact with one or more print surfaces of a substrate. When in contact, the catalyst ink may transfer from the stamp write surface(s) to the substrate print surface(s), thereby creating a reverse version of the stamp pattern on a surface of the substrate. Attraction of one or more components of the catalyst ink (e.g., catalyst nanoparticles, one or more ink additives) to the substrate print surface(s) may be greater than attraction of the catalyst ink component(s) to the stamp write surface(s). The stamping process may be repeated an arbitrary number of times on a substrate (and/or on multiple substrates) for replicating the pattern in different locations. Subsequent electroless plating of the catalyst ink patterns on the substrate(s) may transform those catalyst ink patterns into metal traces. Direct printing using a stamp allows creation of catalyst ink patterns, and corresponding conductive regions after plating, having features at micrometer (μm) or nanometer (nm) scales.

FIG. 1 is a flow chart showing steps of an example method of direct stamp printing of a catalyst ink pattern and plating that pattern. One or more of the steps shown in FIG. 1 may be modified and/or repeated, and/or other steps may be added. In step 11, a catalyst ink may be applied to one or more write surfaces of a stamp.

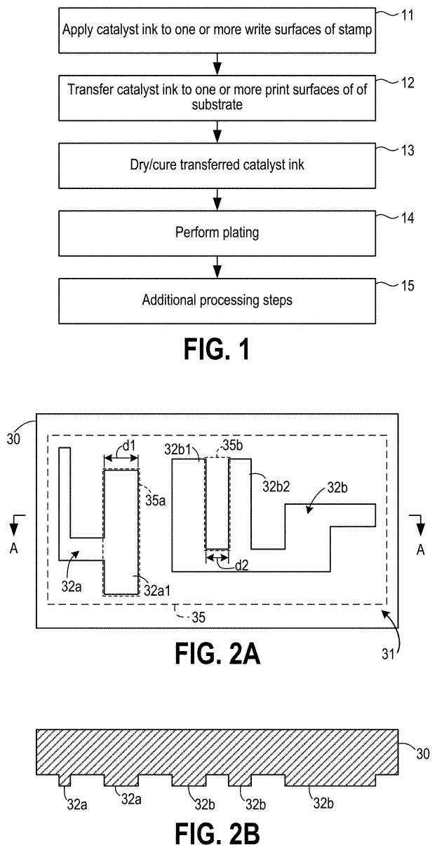

FIG. 2A is a partially schematic plan view of a working face 31 of an example stamp 30 which may be used in the method of FIG. 1. The working face 31 comprises write surfaces 32a and 32b. FIG. 2B is a partially schematic area cross-sectional view of the stamp 30 taken from the plane A-A indicated in FIG. 2A. The write surfaces 32a and 32b may be collectively referred to herein as “the write surfaces 32,” and an arbitrary one of the write surfaces 32a and 32b may be generically referred herein to as “a write surface 32.” The write surfaces 32 are part of a relatively simple and confined pattern selected to facilitate description of one or more example methods. The write surfaces 32 and other structures and/or characteristics of the stamp 30 are merely examples. Stamps having one or more write surfaces with different configurations may also or alternatively be used in methods described herein. Such different configurations may include parts of patterns that are much more complex and/or expansive (e.g., that extend over a much larger stamp face).

The write surfaces 32 may be part of a pattern 35, an approximate boundary of which is indicated in FIG. 2A with large broken lines. The pattern 35 may comprise raised regions that form the write surfaces 32 and valleys that form spaces surrounding and/or separating the write surfaces 32. The pattern 35 may comprise one or more features. A feature may have a shape and/or one or more dimensions. A feature of the pattern 35 may comprise a region corresponding to a write surface or a portion thereof. For example, the pattern 35 may comprise a rectangular feature 35a, corresponding to a portion 32a1 of the write surface 32a, having a dimension (e.g., an edge-to-edge width) d1. A feature of the pattern 35 may comprise a region corresponding to a space between and/or otherwise defined by one or more edges of one or more write surfaces. For example, the pattern 35 may comprise a feature 35b, corresponding to a space between portions 32b1 and 32b2 of write surface 32b, having a dimension d2. Dimensions d1, d2, and/or other dimensions of pattern 35 features may be micrometer (μm) or nanometer (nm) scale values. For example, dimensions d1, d2, and/or other dimensions of pattern 35 features may be less than 100 μm, less than 50 μm, less than 20 μm, less than 10 μm, or smaller. With appropriate stamp patterning and use of sufficiently small nanoparticles, smaller feature dimensions may be achieved (e.g., hundreds of nm scale, tens of nm scale, less than 10 nm scale).

The stamp 30 may comprise a main body formed from one or more parent materials, examples of which are described below. The write surfaces 32 may comprise a parent material of the main body, and/or may comprise one or more surface treatments and/or coatings, examples of which are also described below. The pattern 35 and/or other patterns may, for example, be formed using electron beam lithography, nanoimprint lithography, or other fabrication methods.

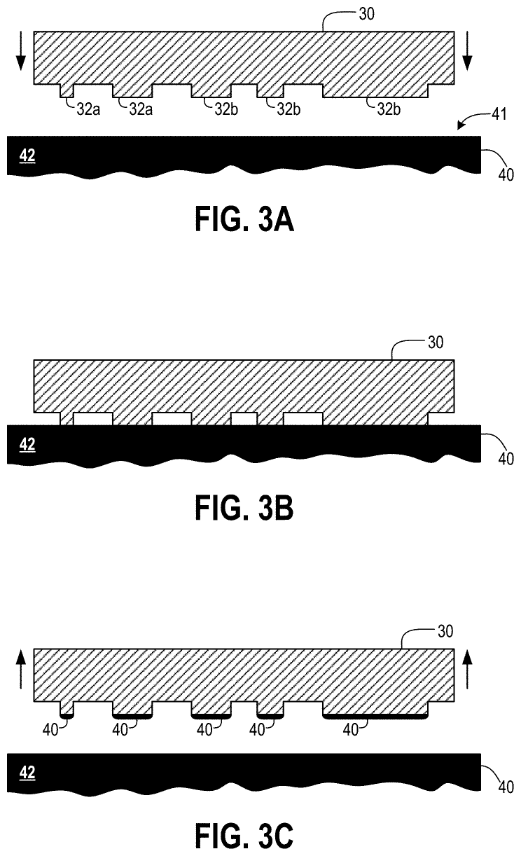

FIGS. 3A through 3C are partially schematic area cross-sectional views showing an example of applying a catalyst ink to the write surfaces 32. For simplicity, the stamp 30 is shown in FIGS. 3A through 3C using the area cross-sectional view from FIG. 2B. Also shown in area cross-sectional view in FIGS. 3A through 3C is a portion of a bath 42 of a catalyst ink 40. The bath 42 may comprise a surface 41 having an area large enough to engage the entirety of the write surfaces 32 in one contact. To apply the catalyst ink 40, and as shown in FIG. 3A, the working face 31 of the stamp 30 may be moved toward the surface 41. That movement may continue until the write surfaces 32 contact the surface 41, as shown in FIG. 3B. The working face 31 may then be moved away from the surface 41, as shown in FIG. 3C. As shown in FIG. 3C, a portion of the catalyst ink 40 from the bath 42 remains on the write surfaces 32. Instead of, or in addition to, a bath as shown in FIGS. 3A-3C, one or more droplets of catalyst ink may be dispensed in a staging area on a substrate, and a stamp dipped into the one or more droplets. Multiple write steps may be performed from a single set of such staging area droplet(s). Also or alternatively, catalyst ink may be applied to write surfaces from a source other than an open bath or staging area droplet(s). For example, the surface 41 may alternatively comprise a surface of a plate or roller to which the catalyst ink 40 has been applied, a surface of a mat or other porous material impregnated with the catalyst ink 40, or a portion of some other structure that holds the catalyst ink 40. Also or alternatively, a stamp may comprise an internal catalyst ink dispense mechanism that comprises an array of one or more channels through which a conformal coat of catalyst ink may flow onto a stamp write surface. Also or alternatively, atomic layer deposition or other thin film material deposition processes (e.g., sputtering, molecular beam epitaxy (MBE), chemical vapor deposition (CVD)) may be used to apply the catalyst ink to the stamp.

The catalyst ink 40 may comprise a catalyst ink such as one or more of the catalyst inks described in U.S. Pat. No. 10,619,059, which patent is incorporated by reference herein. The catalyst ink 40 may be a colloidal solution. Components of the catalyst ink 40 may, for example, comprise catalyst nanoparticles and/or catalyst molecules, one or more solvents, and one or more binders and/or other additives. The catalyst nanoparticles may be palladium (Pd) nanoparticles and/or nanoparticles of one or more other catalyst materials. Examples of other catalyst materials comprise platinum (Pt) and rhodium (Rh). Sizes of the catalyst nanoparticles may, for example, range from 15 nm to 500 nm. A size of a catalyst nanoparticle may, for example, be a largest linear dimension of that nanoparticle (e.g., a diameter of a spherical nanoparticle). A size range of catalyst nanoparticles for a particular catalyst ink may be selected based on resolution of features of a pattern to be printed with that catalyst ink. In general, nanoparticles for a catalyst ink should be smaller than the smallest feature dimension of a pattern to be printed. Although smaller nanoparticle sizes allow for printing of smaller features, larger-sized nanoparticles may be less costly to process and/or handle. Example ranges of catalyst nanoparticle sizes may comprise 5 nm to 100 nm, 5 nm to 50 nm, 5 nm to 10 nm, 15 nm to 500 nm, 15 nm to 400 nm, 15 nm to 300 nm, 15 nm to 200 nm, 15 nm to 100 nm, 15 nm to 50 nm, 50 nm to 500 nm, 50 nm to 400 nm, 50 nm to 300 nm, 50 nm to 200 nm, 50 nm to 100 nm, 100 nm to 500 nm, 100 nm to 400 nm, 100 nm to 300 nm, 100 nm to 200 nm, 200 nm to 500 nm, 200 nm to 400 nm, 200 nm to 300 nm, 300 nm to 500 nm, 300 nm to 400 nm, and 400 nm to 500 nm.

The concentration of catalyst nanoparticles in a catalyst ink may be selected based on a desired viscosity, thickness, and/or other characteristics of a catalyst ink. A catalyst ink formulated for printing may have a higher concentration of catalyst nanoparticles (e.g., to increase reaction rate during electroless plating) than a catalyst ink formulated for application via aerosol jet. A catalyst ink may, for example, contain from 0.1 weight percent (wt %) to 5.0 wt % catalyst nanoparticles. Example ranges of catalyst nanoparticle concentration for a catalyst ink may comprise 0.1 wt % to 5.0 wt %, 0.1 wt % to 4.0 wt %, 0.1 wt % to 3.0 wt %, 0.1 wt % to 2.2 wt %, 0.1 wt % to 1.5 wt %, 0.1 wt % to 0.5 wt %, 0.5 wt % to 5.0 wt %, 0.5 wt % to 4.0 wt %, 0.5 wt % to 3.0 wt %, 0.5 wt % to 2.2 wt %, 0.5 wt % to 1.5 wt %, 1.5 wt % to 5.0 wt %, 1.5 wt % to 4.0 wt %, 1.5 wt % to 3.0 wt %, 1.5 wt % to 2.2 wt %, 2.2 wt % to 5.0 wt %, 2.2 wt % to 4.0 wt %, 2.2 wt % to 3.0 wt %, 3.0 wt % to 5.0 wt %, 3.0 wt % to 4.0 wt %, and 4.0 wt % to 5.0 wt %.

A solvent used for a catalyst ink may comprise any suitable solvent (or combination of solvents) that yields, when mixed with other ingredients, a colloidal solution of the catalyst nanoparticles that is suitable for application to write surface(s) of a stamp and transfer to substrate print surface(s) from the write surface(s). Such solvents include, without limitation, toluene, dimethylformamide, tetrahydrofuran, xylenes, and combinations thereof. Also or alternatively, water may be used as a solvent in some catalyst inks.

One or more binders and/or other additives may be included in a catalyst ink to affect interaction between the catalyst ink and stamp write surfaces and/or between the catalyst ink and substrate print surfaces, to increase viscosity, to minimize wetting, and/or to affect other properties of the catalyst ink. Examples of additives comprise polyvinyl alcohols, cellulose acetate, carboxymethyl cellulose, polyvinylidene fluoride (PVDF), and polyvinyl acetate (PVA). Additives may, for example, have molecular weights in ranges of 10K to 180K.

The components of a catalyst ink may be mixed just prior to application to write surfaces and/or periodically remixed. The mixing and/or remixing may, for example, comprise sonification to disperse catalyst nanoparticles in the solution and/or prevent aggregation and/or settling. For example, sonification may be applied to the bath 42 prior to placement of the write surfaces 32 into contact with the surface 41, after the write surfaces 32 are removed from contact with the surface 41 and prior to a subsequent placement of the write surfaces 32 into contact with the surface 41, etc. Also or alternatively, sonification may be applied continuously to the bath 42.

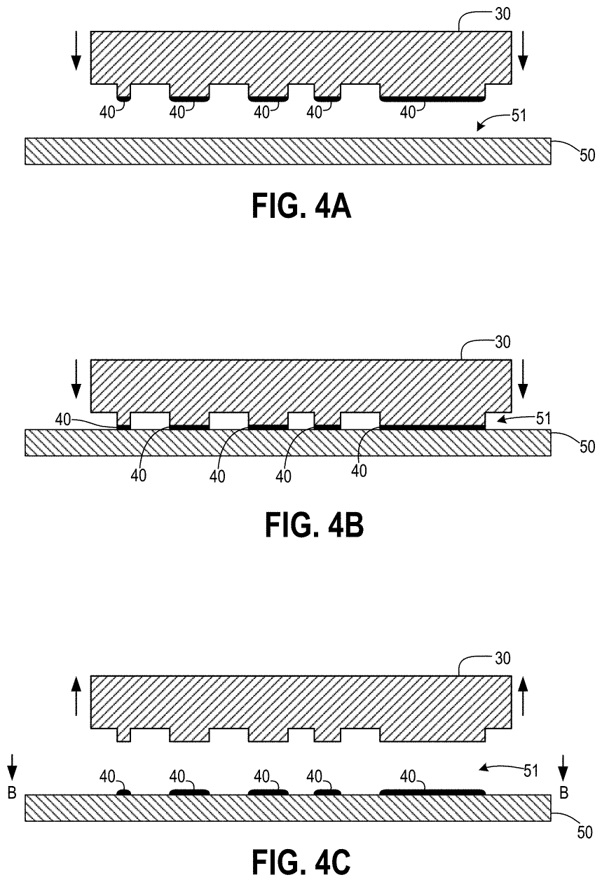

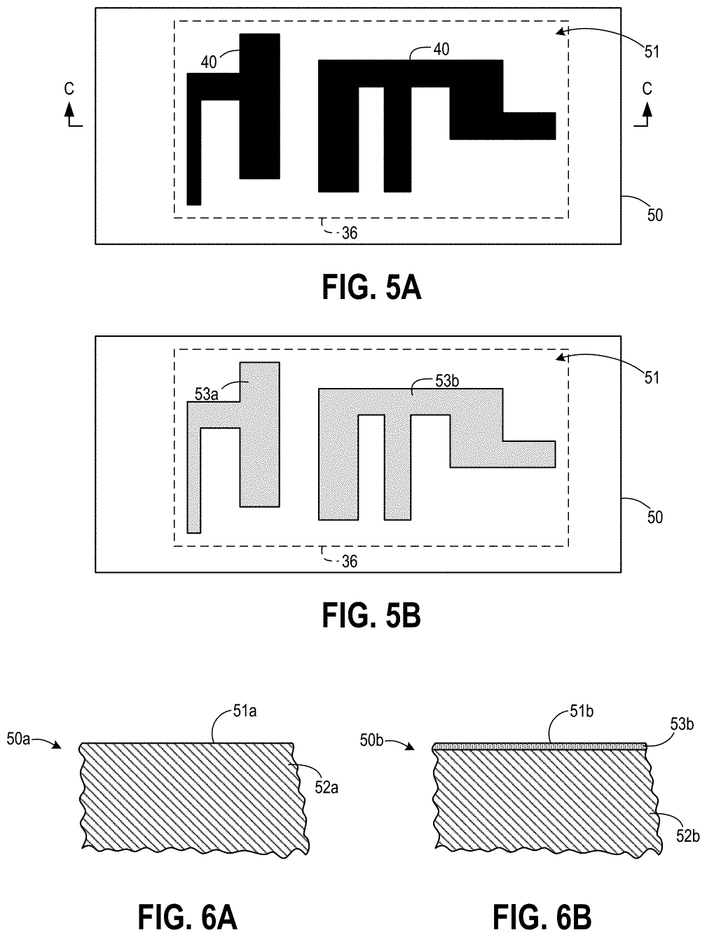

In step 12 (FIG. 1), the catalyst ink 40 applied to the write surfaces 32 may be transferred to a print surface of a substrate. FIGS. 4A through 4C are partially schematic area cross-sectional views showing an example of transferring the catalyst ink 40 to a print surface 51 of a substrate 50. As in FIGS. 3A through 3C, the stamp 30 is shown in FIGS. 4A through 4C using the area cross-sectional view from FIG. 2B. The substrate 50 is shown in FIGS. 4A through 4C in an area cross-sectional view from the plane C-C indicated in FIG. 5A. As shown in FIGS. 4A and 4B, the catalyst ink 40 may be transferred by moving the stamp 30 to place the catalyst ink 40, applied to the write surfaces 32, into contact with the print surface 51. Subsequently, and as shown in FIG. 4C, the stamp 30 may be moved away from the substrate 50. As the stamp 30 is moved away, some or all of the catalyst ink 40 previously on the write surfaces 32 adheres to and remains on the print surface 51. As described below, the print surface 51 may be coated with and/or otherwise formed from one more materials to promote adhesion and/or to minimize wetting.

To achieve the relative motions shown in FIGS. 3A through 4C, the stamp 30 and/or the substrate 50 may be manipulated using automated handling equipment (e.g., a movable stage for shifting the position of the substrate 50 relative to the stamp 30 and/or a stamp manipulator such as a robotic arm). Existing handling equipment (e.g., such as is used in nanoimprint lithography processes) may be adapted for such manipulation. Although the example of FIGS. 3A through 4C shows transfer of catalyst ink from multiple write surfaces to a single print surface, the method of FIG. 1 may comprise transfer of ink from one or more write surfaces to one or more print surfaces. For example, the stamp 30 could be used to simultaneously print a first portion of a pattern 36 (FIG. 5A) corresponding to the write surface 32a on a print surface of a first substrate and print a second portion of the pattern 36 corresponding to the write surface 32b on a print surface of a second substrate positioned alongside the first substrate.

FIG. 5A is a partially schematic plan view, from the plane B-B indicated in FIG. 4C, of the substrate 50 print surface 51 after transfer of the catalyst ink 40. As shown in FIG. 5A, the transferred catalyst ink 40 forms the printed pattern 36 that corresponds to (e.g., is a reverse of) the pattern 35. In step 13 (FIG. 1), the catalyst ink 40 transferred to the print surface 51 may be dried and/or otherwise cured. Step 13 may comprise allowing the catalyst ink 40 to air dry, and/or may comprise applying heat, light, ultraviolet (UV) light (e.g., if the catalyst ink 40 comprises a UV curing agent), dry air, and/or other processing to the catalyst ink 40.

In step 14, electroless plating may be performed to plate the catalyst ink 40 of the printed pattern 36. During the plating of step 14, the catalyst ink 40 may be metallized with a plating metal (e.g., with copper (Cu), gold (Au), silver (Ag), Aluminum (Al), Nickel (Ni), or Iron (Fe)). The plating of step 14 may comprise immersing the print surface 51 in an electroless plating bath containing an electroless plating solution. Also or alternatively, microdroplets of an electroless plating solution may be applied to the catalyst ink 40 in the printed pattern 36. Electroless plating solutions to plate copper to a Pd catalyst, as well as to plate any of a variety of other plating metals to Pd or to other catalysts, are known. After a plating time has elapsed, which time may be determined based on plating solution chosen, the print surface 51 may be removed from the electroless plating bath and/or the electroless plating solution otherwise removed (e.g., with compressed air or other drying process). FIG. 5B is a partially schematic plan view of the print surface 51 after step 14. As shown in FIG. 5B, the catalyst ink 40 has been transformed into metal traces 53a and 53b.

In step 15 one or more additional processes may be performed. The one or more additional processes may, for example, comprise washing (e.g., with water, with acid, etc.), application of anti-tarnish compounds, application of other materials, etc. Also or alternatively, step 15 may comprise repeating one or more of steps 11 through 14. For example, additional catalyst ink may be printed (e.g., using the stamp 30 or another stamp) on some or all of the metal trace 53a and/or the metal trace 53b. Electroless plating may subsequently be performed on the additional catalyst ink. Multiple printing and plating steps may be performed, for example, to obtain a thicker layer of plating metal in one or more regions.

Also or alternatively, one or more other materials (e.g., a layer of non-conductive material) may be applied onto some or all of the metal trace 53a and/or the metal trace 53b. Additional catalyst ink may then be printed onto those one or more other materials, and electroless plating subsequently performed on that additional catalyst ink. The resulting article may comprise layers of metal traces separated by an insulating material.

Stamps and/or substrates may comprise any of a variety of materials. Those materials, and/or components of a catalyst ink, may be selected to improve adherence of catalyst ink to a write surface, release of catalyst ink from a write surface, transfer of catalyst ink from a write surface to a print surface, adherence of catalyst ink to a print surface, wettability of a print surface by a catalyst ink (e.g., to inhibit a catalyst ink from spreading beyond desired regions of a printed pattern), and/or other interactions between the catalyst ink and the write surface and/or print surface. Although several specific examples are described below, other materials, combinations of materials, and/or surface treatments may also or alternatively be used.

A print surface of a substrate may comprise a surface of a parent material forming some or all of the remaining structure of the substrate. Also or alternatively, a substrate print surface may comprise a material (e.g., a coating) applied to the substrate parent material and/or to another material (e.g., an intermediate coating) fixed to the substrate parent material. For example, FIG. 6A is an enlarged, partially schematic, area cross-sectional view of a portion of a substrate 50a. The substrate 50a is formed from a parent material 52a. A print surface 51a comprises a region of a surface of the parent material 51a. As another example, FIG. 6B is an enlarged, partially schematic, area cross-sectional view of a portion of a substrate 50b. The substrate 50b is formed from a parent material 52b. A print surface 51b comprises a surface of a material 53b applied to a region of the surface of the parent material 52b. Similarly, a write surface of a stamp may comprise a surface of a parent material forming some or all of the remaining structure of the stamp. Also or alternatively, a stamp write surface may comprise a material (e.g., a coating) applied to the stamp parent material and/or to another material (e.g., an intermediate coating) fixed to the stamp parent material.

A stamp may be formed from metallic, ceramic, or organic parent materials. For example, a stamp parent material may comprise steel or other metal or metal alloy, a metallic and/or inorganic silicate, a ceramic (e.g., (ZnMg)TiO₃), a dielectric such as a polyimide-based polymer (e.g., such as is found in KAPTON film), and/or other materials. To promote capture of catalyst ink by a write surface, the write surface may comprise a coating or a monolayer with chemical properties selected to enhance temporary catalyst ink bonding. Examples of materials for such coatings and monolayers comprise surface modifying compounds such as those described below.

Substrates may also be formed from any of a variety of parent materials. Examples of substrate parent materials comprise ceramic dielectric materials, organic dielectric materials, metals or metal alloys, polymers, and/or other materials. A substrate print surface may comprise a coating or monolayer of one more materials that are different from a parent material of the substrate. For example, print surfaces of substrates formed from more rigid parent materials may comprise a coating of a more flexible material. Such flexible materials may, for example, comprise a polyimide material (e.g., KAPTON film), PVA, cellulose acetate, PVDF, and/or another polymer material. A flexible print surface material may promote more complete catalyst ink transfer from write surface(s) of a stamp by, for example, facilitating embedding of catalyst nanoparticles in the print surface and/or compensating for minute imperfections in stamp write surface(s). Also or alternatively, a substrate print surface may comprise a coating or a monolayer with chemical properties selected to enhance temporary catalyst attraction to the print surface.

To promote and/or enhance transfer of catalyst ink from a stamp write surface to a substrate print surface, one or more stamp write surface materials, one or more substrate print surface materials, and/or one or more catalyst ink components may be selected so that attraction of one or more components of the catalyst ink to the substrate print surface is greater than attraction of the catalyst ink component(s) to the stamp write surface. For example, a substrate print surface may comprise a coating and/or monolayer (e.g., a self-assembled monolayer (SAM)) formed from one or more surface modifying compounds applied to a parent material of the substrate. A surface modifying compound may comprise a chemical having a terminating functional group that binds to the substrate parent material and a tail functional group that attracts a component of the catalyst ink more strongly than such catalyst ink component is attracted by material of a stamp write surface.

A surface modifying compound may be selected so that a tail functional group of that compound attracts the catalyst nanoparticles of the catalyst ink. For example, Pd nanoparticles are attracted by tail functional groups that comprise amines. Tail functional groups that comprise sulfur and/or phosphorous may also be used to attract a variety of metals, including Pd and Pt. Phosphorus- and/or phosphine-based tail functional groups may be used to attract Rh. Attraction of Pd, Pt, and/or Rh nanoparticles to such tails would be greater than attraction to steel, other metals and metal alloys, and inorganic silicates that may be used as substrate or stamp parent materials.

Selection of a surface modifying compound may also be based on a substrate parent material to which the compound will be applied. For example, amine and sulfur functional groups bond to iron- and copper-based materials. As another example, carboxylate functional groups bond to zinc-based materials.

A surface modifying compound may, for example, comprise a silane-based surface modifying compound. Silane surface modifying compounds known to bond to a large variety of materials, having known chemical structures, and/or having other properties (e.g., hydrophobicity, hydrophilicity) are commercially available. A surface modifying compound need not be a silane. For example, a surface modifying compound may comprise graphene oxide. Table 1 comprises a non-exhaustive list of example surface modifying compounds for various combinations of parent materials (to which a surface modifying compound may be applied) and catalyst nanoparticle materials.

TABLE 1
Example Surface Modifying Compounds

| | Catalyst | Example |
|---|---|---|
| Parent | Nanoparticle | Surface Modifying |
| Material | Material | Compound |
| iron and/or | Pd | Amine terminated with |
| steel | | linkage to sulfur or |
| | | phosphine |
| copper and/or | Pd | Amine terminated with |
| copper alloys | | linkage to sulfur or |
| | | phosphine |
| zinc and/or | Pd | Amine or carboxylate |
| zinc alloys | | terminated with linkage |
| | | to sulfur or phosphine |
| titanium and | Pd | Epoxy or hydride |
| or titanium | | terminated with linkage |
| alloys | | to sulfur or phosphine |
| tin and/or tin | Pd | Amine terminated with |
| alloys | | linkage to sulfur or |
| | | phosphine |
| Silica oxide | Pd | Silicon chloride |
| | | terminated with linkage |
| | | to sulfur or phosphine |

Also or alternatively, materials may be selected so that attraction of one or more other catalyst ink components to a substrate print surface is greater than attraction of the other catalyst ink component(s) to a stamp write surface. For example, and for catalyst inks comprising organic solvents, PVDF and/or PVA may be added. PVDF and/or PVA will promote adhesion to organic substrate print surface materials, and may lessen adhesion to metallic and inorganic stamp write surface materials.

Also or alternatively, write surface materials, print surface materials, and/or catalyst ink components may be selected so that attraction of one or more catalyst ink components to a write surface is enhanced and/or greater than attraction of such catalyst ink component(s) to a print surface. For example, materials such as those described above for a print surface may be used for a write surface, and/or materials such as those described above for a write surface may be used for a print surface. Moreover, write surface materials, print surface materials, and/or catalyst ink components may also or alternatively be selected based on wettability of a print surface and/or write surface by a catalyst ink. Increased hydrophobicity/reduced wettability may reduce the tendency of printed catalyst ink to spread beyond print surface regions where that catalyst ink is initially deposited by a stamp write surface.

Also or alternatively, metallic stamp write surfaces and/or metallic substrate print surfaces may be laser or plasma treated. Laser surface treatment may, for example, create microscopic pitting and/or other surface features that increase retention of catalyst ink. Plasma surface treatment may, for example, activate a surface by ionizing atoms of the surface material, thereby increasing the tendency of the surface to retain catalyst ink.

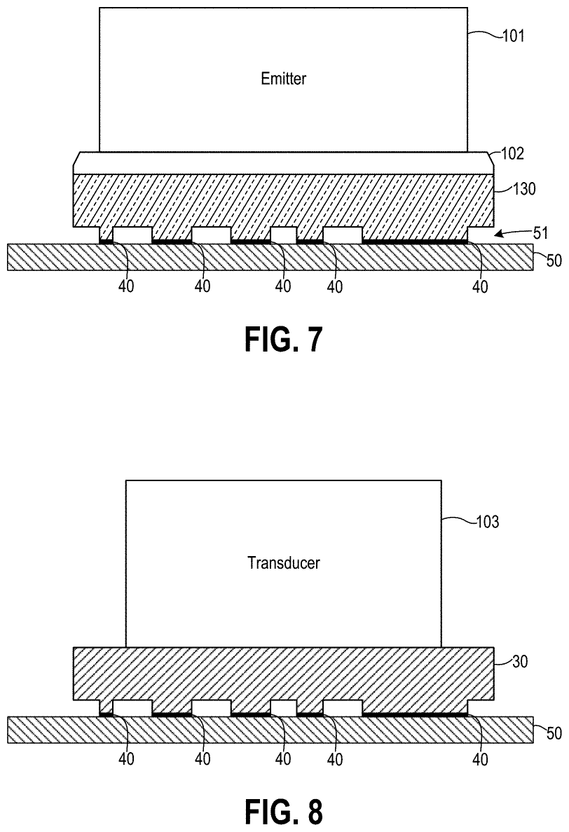

As indicated above, catalyst ink may be treated with laser or UV light to cure that catalyst ink. Such curing may increase the adhesion of the catalyst ink to a print surface and/or accelerate evaporation of solvent from the catalyst ink. Such laser or UV treatment may be performed after catalyst ink has been applied to stamp write surface(s) and before transfer to substrate print surface(s), and/or may be performed as catalyst ink is being transferred from a stamp to a substrate. FIG. 7 shows an example configuration of a stamp 130 to provide such treatment. In FIG. 7, the stamp 130 is shown using an area cross-sectional view from a plane similar to the plane A-A of FIG. 2A and the substrate 50 is shown using an area cross-sectional view from the plane C-C FIG. 5A. The stamp 130 may similar to the stamp 30 in size and general configuration and may have working face pattern similar to the pattern 35. However, the stamp 130 is formed from a transparent material. A laser or UV emitter 101 (shown schematically) may be coupled to the stamp 130 by a lens/light guide 102 (also shown schematically). As the catalyst ink 40 on write surfaces of the stamp 130 contacts the print surface 51 of the substrate 50, laser or UV light from the emitter 101 may be transmitted via the lens/light guide 102 and the stamp 130 into the catalyst ink 40. Also or alternatively, laser and/or UV light may be transmitted to the catalyst ink 40 via light guide(s) formed in space(s) surrounding some or all write surfaces and/or from a source not coupled to the stamp 130. The catalyst ink 40 may comprise one or more curing agents that are activated by laser or UV light.

As indicated above, sonification may be used to promote transfer of catalyst ink from stamp write surface(s) to substrate print surface(s). FIG. 8 shows an example configuration of the stamp 30 to provide such treatment. In FIG. 8, the stamp 30 is shown using an area cross-sectional view from the plane A-A of FIG. 2A and the substrate 50 is shown using an area cross-sectional view from the plane C-C FIG. 5A. A sonic transducer 103 (shown schematically) may be coupled to the stamp 30. As the catalyst ink 40 on write surfaces of the stamp 30 contacts the print surface 51 of the substrate 50, the transducer 103 may be activated to generate ultrasonic energy that is transmitted via the stamp 30 into the catalyst ink 40.

The configurations of FIG. 7 and FIG. 8 may be combined. Moreover, the configurations of FIG. 7 and/or FIG. 8 may be used in connection with stamps having write surface coatings or treatments and/or with substrates having print surface coatings or treatments.

A stamp may also be used to transfer catalyst ink from and/or to surfaces that are not flat. For example, one or more stamp write surfaces be portions of a complex surface, which surface also corresponds to one or substrate print surfaces. Catalyst ink may be applied to non-flat write surfaces using, e.g., a roller or porous body that conforms to the non-flat write surfaces. Also or alternatively, a stamp may be flexible and, after application of catalyst ink to write surfaces of that stamp in a flat configuration, able to conform to a non-flat substrate print surface.

Write surfaces of a stamp need not be fixed. For example, a stamp working face may comprise one or more pins or other structures that can be extended or retracted to create a desired pattern.

The foregoing has been presented for purposes of example. The foregoing is not intended to be exhaustive or to limit features to the precise form disclosed. The examples discussed herein were chosen and described in order to explain principles and the nature of various examples and their practical application to enable one skilled in the art to use these and other implementations with various modifications as are suited to the particular use and/or uses contemplated. The scope of this disclosure encompasses, but is not limited to, any and all combinations, subcombinations, and permutations of structure, operations, materials, and/or other features described herein and in the accompanying drawing figures.

1. A method comprising:
applying catalyst ink to one or more write surfaces of a printing stamp, wherein
the catalyst ink comprises palladium nanoparticles and
portions of the one or more write surfaces are separated by one or more spaces;
transferring the applied catalyst ink to one or more print surfaces of a substrate by moving the printing stamp to place the applied catalyst ink in contact with the one or more print surfaces, wherein the transferred catalyst ink forms a printed pattern, on the one or more print surfaces, that corresponds to a stamp pattern defined, at least in part, by the one or more write surfaces and the one or more spaces; and
electroless plating the printed pattern with copper.

2. The method of claim 1, wherein one or more features of the stamp pattern have a width of less than 50 microns.

3. The method of claim 1, wherein attraction of one or more components of the catalyst ink to the one or more print surfaces is greater than an attraction of the one or more components to the one or more write surfaces.

4. The method of claim 1, wherein
the one or more print surfaces comprise an organic material and
the catalyst ink further comprises one or more of polyvinyl acetate or polyvinylidene fluoride.

5. The method of claim 1, wherein
the one or more print surfaces comprise a surface modifying compound bonded to a parent material of the substrate,
the surface modifying compound comprises a terminating functional group and a tail functional group, and wherein
attraction of the palladium nanoparticles to the tail functional group is greater than attraction of the palladium nanoparticles to the parent material of the substrate.

6. The method of claim 5, wherein
the one or more write surfaces comprise at least one of a metal, a metal alloy, or an inorganic silicate and
attraction of the palladium nanoparticles to the tail functional group is greater than an attraction of the palladium nanoparticles to the one or more write surfaces.

7. The method of claim 1, wherein
the one or more write surfaces comprise at least one of a metal, a metal alloy, or an inorganic silicate and
the catalyst ink comprises one or more of polyvinyl acetate or polyvinylidene fluoride.

8. The method of claim 1, wherein the one or more print surfaces comprise one or more of a polyimide based polymer, polyvinyl acetate, polyvinylidene fluoride, or cellulose acetate.

9. The method of claim 1, further comprising exposing, prior to or during the transferring, the applied catalyst ink to laser light or ultraviolet light.

10. The method of claim 1, further comprising applying, during the transferring, sonic energy to the stamp.

11. The method of claim 1, wherein the one or more write surfaces comprise one or more of a plasma-etched surface or a laser-treated surface.

12. A method comprising:
applying catalyst ink to one or more write surfaces of a printing stamp, wherein
the catalyst ink comprises catalyst nanoparticles and
portions of the one or more write surfaces are separated by one or more spaces;
transferring the applied catalyst ink to one or more print surfaces of a substrate by moving the printing stamp to place the applied catalyst ink in contact with the one or more print surfaces, wherein
attraction of one or more of components of the catalyst ink to the one or more print surfaces is greater than an attraction of the one or more components to the one or more write surfaces, and
the transferred catalyst ink forms a printed pattern, on the one or more print surfaces, that corresponds to a stamp pattern defined, at least in part, by the one or more write surfaces and the one or more spaces; and
electroless plating the printed pattern with a plating metal.

13. The method of claim 12, wherein
the one or more write surfaces comprise one or more of a metal, a metal alloy, or an inorganic silicate,
the one or more of components of the catalyst ink comprise one or more of polyvinyl acetate or polyvinylidene fluoride, and
the one or more print surfaces comprises an organic material.

14. The method of claim 12, wherein
the catalyst nanoparticles comprise one or more of rhodium, platinum, or palladium and
the plating metal comprises copper.

15. The method of claim 12, wherein
the one or more print surfaces comprise a surface modifying compound bonded to a parent material of the substrate,
the surface modifying compound comprises a terminating functional group bonded to the parent material and a tail functional group, and
attraction of the catalyst nanoparticles to the tail functional group is greater than an attraction of the catalyst nanoparticles to the parent material.

16. The method of claim 15, wherein the tail functional group comprises an amine.

17. The method of claim 15, wherein
the surface modifying compound comprises a silane compound and
the parent material comprises a one or more of a metal, a metal alloy, or an inorganic silicate.

18. The method of claim 12, wherein the one or more print surfaces comprises one or more of a polyimide based polymer, polyvinyl acetate, polyvinylidene fluoride, or cellulose acetate.

19. The method of claim 12, further comprising applying, during the transferring, sonic energy to the stamp.

20. The method of claim 12, wherein one or more features of the stamp pattern have a width of less than 50 microns.
